(19) United States
(12) Patent Application Publication
(10) Pub. No.: US 2025/0393258 A1
(43) Pub. Date: Dec. 25, 2025

(54) SEMICONDUCTOR DEVICE HAVING NANOSHEET TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Chih Sheng HUANG, New Taipei City (TW); Chih-Chiang CHANG, Hsinchu (TW); Ming-Hua YU, Hsinchu (TW)

(21) Appl. No.: 18/747,525

(22) Filed: Jun. 19, 2024

(51) Int. Cl. H01L 29/78; H01L 21/02; H01L 29/06; H01L 29/08; H01L 29/423; H01L 29/45; H01L 29/66; H01L 29/775; H01L 29/786

(52) U.S. Cl. CPC H10D 30/797; H01L 21/02532; H10D 30/014; H10D 30/031; H10D 30/43; H10D 30/6735; H10D 30/6757; H10D 62/121; H10D 62/151; H10D 64/017; H10D 64/62

(57) ABSTRACT

A semiconductor device structure includes a plurality of semiconductor layers vertically stacked, a gate electrode layer surrounding a portion of each of the plurality of the semiconductor layers, a gate dielectric layer disposed between the gate electrode layer and each of the semiconductor layer, a first source/drain feature in contact with a sidewall of each of the semiconductor layers, wherein the first source/drain feature comprises a first semiconductor material. The structure also includes a dielectric spacer in contact with the gate dielectric layer, and a protection layer in contact with the dielectric spacer and the first source/drain feature, wherein the protection layer comprises a second semiconductor material that is chemically different than the first semiconductor material.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down presents new challenge. For example, transistors using nanostructure channels have been proposed to improve carrier mobility and drive current in a device. An inner spacer is often disposed between metal gate and source/drain (S/D) structure to protect the S/D structure during the subsequent gate replacement process. Although the formation of the inner spacer has been generally adequate for their intended purposes, the S/D structure may still suffer from damage due to etchant leakage during the gate replacement process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure in accordance with some embodiments.

FIGS. 7-9, 10, 11, and 14-20 are cross-sectional side views of the various stages of manufacturing the semiconductor device structure of FIG. 6 taken along line A-A.

FIGS. 9A and 9B illustrate an enlarged view of a portion of the semiconductor device structure of FIG. 9 in accordance with some embodiments.

FIGS. 11B and 11C are top views of a portion of the semiconductor device structure taken along cross-sections B-B and C-C of FIG. 11, respectively, in accordance with some embodiments.

FIG. 11-1 is an enlarged view of a portion of the semiconductor device structure of FIG. 11, in accordance with some embodiments.

FIG. 12 is a cross-sectional view of the semiconductor device structure, in accordance with some alternative embodiments.

FIGS. 13-1 and 13-2 are cross-sectional views of the semiconductor device structure, in accordance with some alternative embodiments.

FIGS. 20B and 20C are top views of a portion of the semiconductor device structure taken along cross-sections B-B and C-C of FIG. 20, respectively, in accordance with some embodiments.

FIGS. 20-1 and 20-2 are cross-sectional views of the semiconductor device structure taken along line 1-1 and line 2-2 of FIG. 20, respectively.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

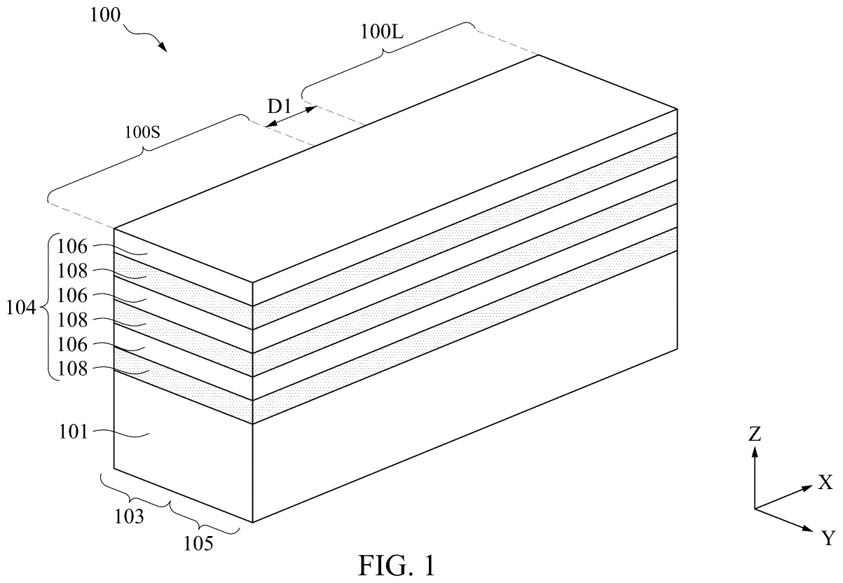

FIGS. 1 to 20-2 show exemplary processes for manufacturing a semiconductor device structure 100 according to embodiments of the present disclosure. It is understood that additional operations can be provided before, during, and after processes shown by FIGS. 1 to 20-2, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100 in accordance with some embodiments. The semiconductor device structure 100 may represent a portion of a larger IC structure and can include short channel regions 100S (only one is shown) and long channel regions 100L (only one is shown) at respective portions of the semiconductor device structure 100. The short channel region 100S and the long channel region 100L may be separated from each other by a distance “D1”, which may be any suitable distance depending on the application. While the short channel region 100S is shown adjacent to the long channel region 100L along the X direction, the long channel region 100L may be located at different regions of the substrate 101.

The semiconductor device structure 100 can be structured to include a plurality of so-called short channel devices and a plurality of so-called long channel devices. The channel length of the long channel devices is typically greater than the channel length of the short channel devices. The transistors to be formed in the short channel region 100S are considered as short channel devices while the transistors to be formed in the long channel region 100L are considered as long channel devices. Short channel devices typically have a threshold voltage that is less than the threshold voltage of long channel devices. In general, the short channel devices exhibit faster switching speeds and higher off-state leakage currents. Short channel devices are often employed in portions of an integrated circuit where fast switching speeds of the transistors is desired, e.g., the logic or computational circuits in an integrated circuit product, a section of the IC product where the switching speed of the transistors is more important than controlling the off-state leakage current of such transistors. In contrast, long channel devices are employed as circuit elements in circuits where the switching speed of the transistors is less desired than their ability to exhibit low off-state leakage currents. For example, long channel devices may be employed in input/output circuits so as to reduce power consumption when the integrated circuit product is turned off.

The semiconductor device structure 100 includes a substrate 101 which may include any currently-known or later developed material capable of being processed into a transistor device. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (e.g., oxide) disposed between two silicon layers for enhancement.

The substrate 101 may include various regions that have been doped with impurities (e.g., dopants having p-type or n-type conductivity). Depending on circuit design, the dopants may be, for example boron for an p-type field effect transistors (PFET) and phosphorus for a n-type field effect transistors (NFET). In one exemplary embodiment, the substrate 101 is formed to include a first device region 103 for forming N-type devices, such as NMOS devices (e.g., N-type gate all around transistors) and a second device region 105 for forming P-type devices, such as PMOS devices (e.g., P-type gate all around transistors). To separate the first device region 103 and the second device region 105, wells may be formed within the substrate 101 with N-type dopants and P-type dopants. To form the desired wells, the N-type dopants and the P-type dopants are implanted into the substrate 101 depending upon the devices to be formed. For example, N-type dopants such as phosphorous or arsenic may be implanted to form N-type wells, while P-type dopants such as boron may be implanted to form P-type wells. The N-type wells and P-type wells may be formed using one or more implantation techniques, such as diffusion implantations, ion implantations (e.g., plasma doping, beam line implant doping), selective implantations, deep-well implantations, and the like, or combinations thereof. Masking techniques may also be utilized to mask some regions (e.g., second device region 105) of the substrate 101 while exposing other regions (e.g., first device region 103) of the substrate 101 during a first well implantation (e.g., N-type wells) process. Once the first well implantation process has been completed, the mask is removed to expose the previously masked regions (e.g., second device region 105) and another mask may be placed over the previously exposed regions (e.g., first device region 103) during a second well implantation (e.g., P-type wells) process. While the first device region 103 is shown adjacent to the second device region 105, it is understood that the first device region 103 may be disposed away from the second device region 105 at different regions of the substrate 101 along the X direction or Y direction, and the first and second device regions 103, 105 belong to a continuous substrate (e.g., substrate 101).

A stack of semiconductor layers 104 is formed over the substrate 101. The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by the gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

As will be described in more detail below, the first semiconductor layers 106 may serve as channels for the semiconductor device structure 100 and the thickness is chosen based on device performance considerations. In some embodiments, each first semiconductor layer 106 has a thickness ranging from about 1 nanometers (nm) to about 15 nm. The second semiconductor layers 108 may eventually be removed and serve to define a vertical distance between adjacent channels for the semiconductor device structure 100 and the thickness is chosen based on device performance considerations. In some embodiments, each second semiconductor layer 108 has a thickness ranging from about 1 nm to about 15 nm. It should be understood that each first semiconductor layer 106 and each second semiconductor layer 108 in the stack 104 need not be formed to the same thickness, although that may be the case in some applications.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

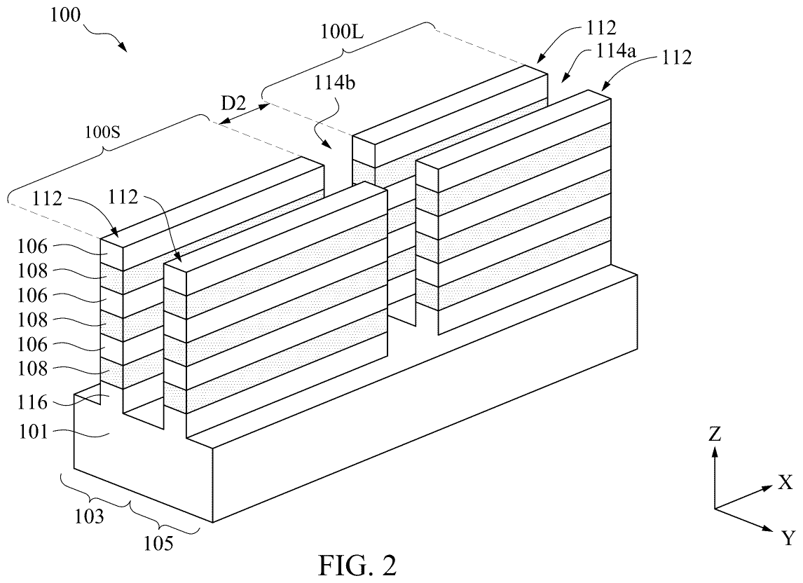

In FIG. 2, fins 112 are formed from the stack of semiconductor layers 104 and a portion of the substrate 101 in the short channel regions 100S and the long channel regions 100L. Each fin 112 has an upper portion including the semiconductor layers 106, 108 and a well portion 116 formed from the substrate 101. The fins 112 may be formed by patterning a hard mask layer (not shown) formed on the stack of semiconductor layers 104 using patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114a and 114b in unprotected regions through the hard mask layer, through the stack of semiconductor layers 104, and into the substrate 101, thereby leaving the plurality of extending fins 112. The trench 114a extends along the X direction while the trench 114b extends along the Y direction. The trench 114b has a width “D2” that substantially corresponds to the distance “D1” shown in FIG. 1. The fins 112 in the short channel regions 100S are separated from the fins 112 in the long channel regions 100L by the distance “D2”. The trenches 114a and 114b may be etched using a dry etch (e.g., RIE), a wet etch, and/or combination thereof.

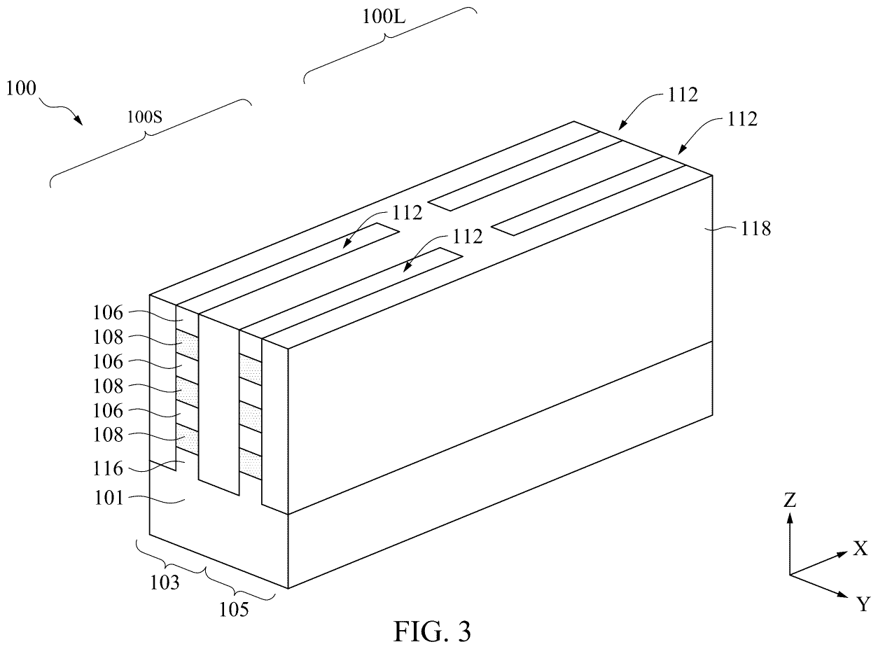

In FIG. 3, after the fins 112 are formed, an insulating material 118 is formed in the trenches 114a and 114b so that the fins 112 in the short channel regions 100S and the long channel regions 100L are embedded in the insulating material 118. Then, a planarization operation, such as a chemical mechanical polishing (CMP) method and/or an etch-back method, is performed such that the top of the fins 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

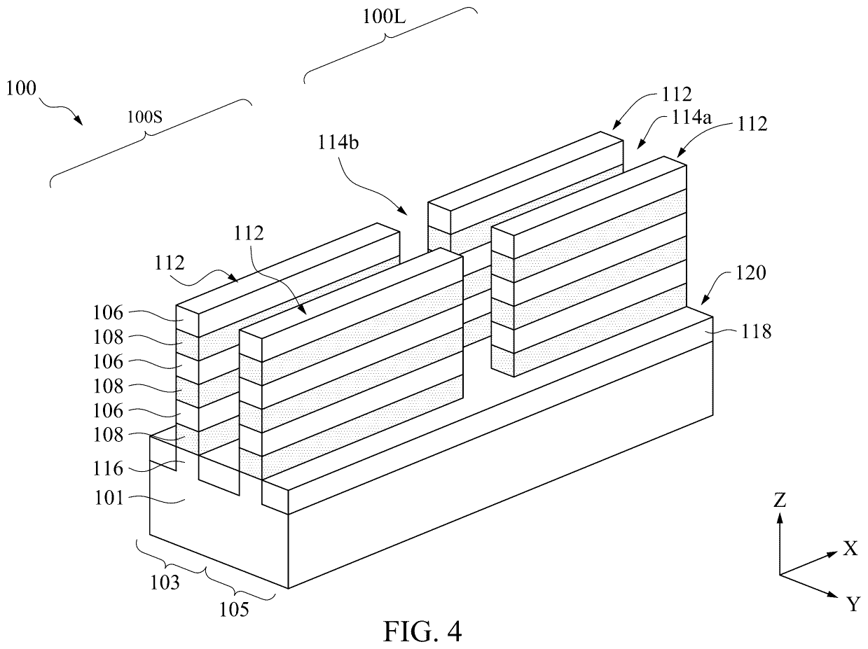

In FIG. 4, the insulating material 118 is recessed to form an isolation region 120. The recess of the insulating material 118 exposes portions of the fins 112, such as the stack of semiconductor layer 104, in the short channel regions 100S and the long channel regions 100L. The recess of the insulating material 118 results in the trenches 114a and 114b between the neighboring fins 112. The isolation region 120 may be formed using a suitable a dry etching process, a wet etching process, or a combination thereof. A top surface of the insulating material 118 may be level with or below a surface of the second semiconductor layers 108 in contact with the well portion 116 formed from the substrate 101.

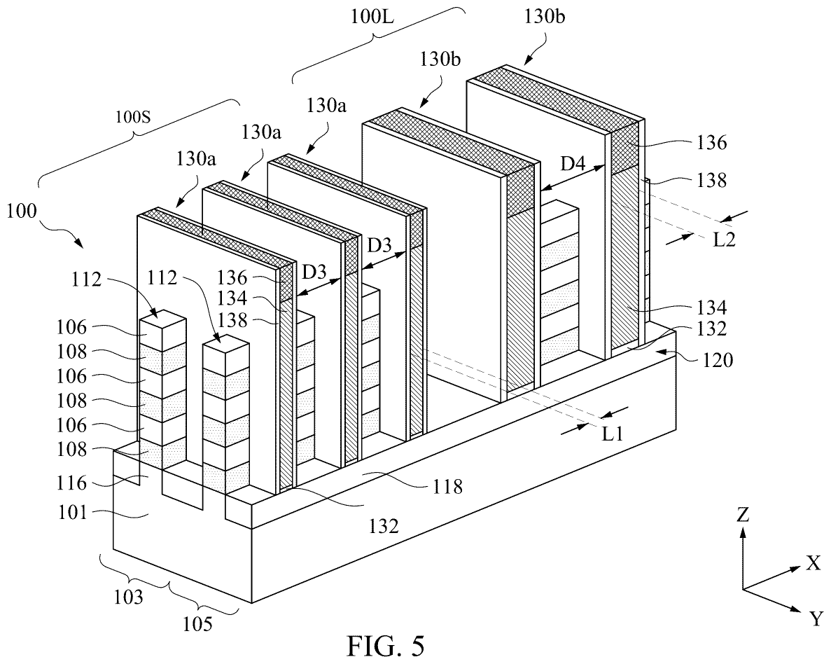

In FIG. 5, sacrificial gate structures 130a, 130b are formed over the semiconductor device structure 100. The sacrificial gate structures 130a and 130b are formed over a portion of the fins 112 in the short channel regions 100S and the long channel regions 100L, respectively. Each sacrificial gate structure 130a, 130b may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially forming respective layers, and then patterning those layers into the sacrificial gate structure 130. Gate spacers 138 are then formed on sidewalls of the sacrificial gate structures 130a, 130b. The gate spacers 138 may be formed by conformally depositing one or more layers for the gate spacers 138 and anisotropically etching the one or more layers, for example.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

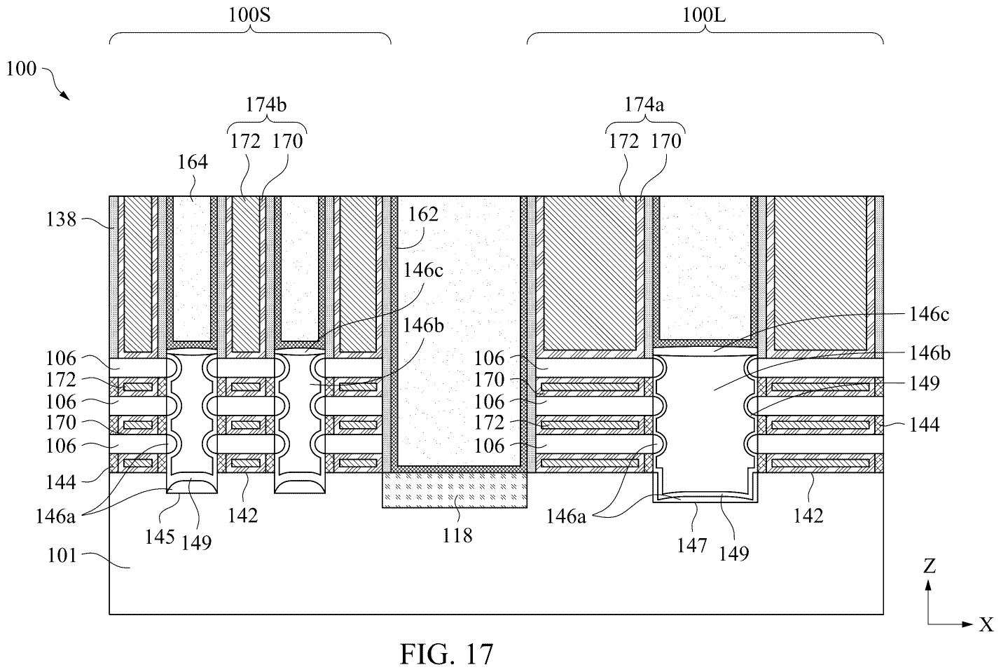

The portions of the fins 112 in the short channel region 100S that are covered by the sacrificial gate electrode layer 134 (to be replaced with a gate electrode layer 172 shown in FIG. 17) of the sacrificial gate structure 130a serve as channel regions for the short channel devices. Likewise, the portions of the fins 112 in the long channel region 100L that are covered by the sacrificial gate electrode layer 134 (to be replaced with gate electrode layer 172 shown in FIG. 17) of the sacrificial gate structure 130b serve as channel regions for the long channel devices.

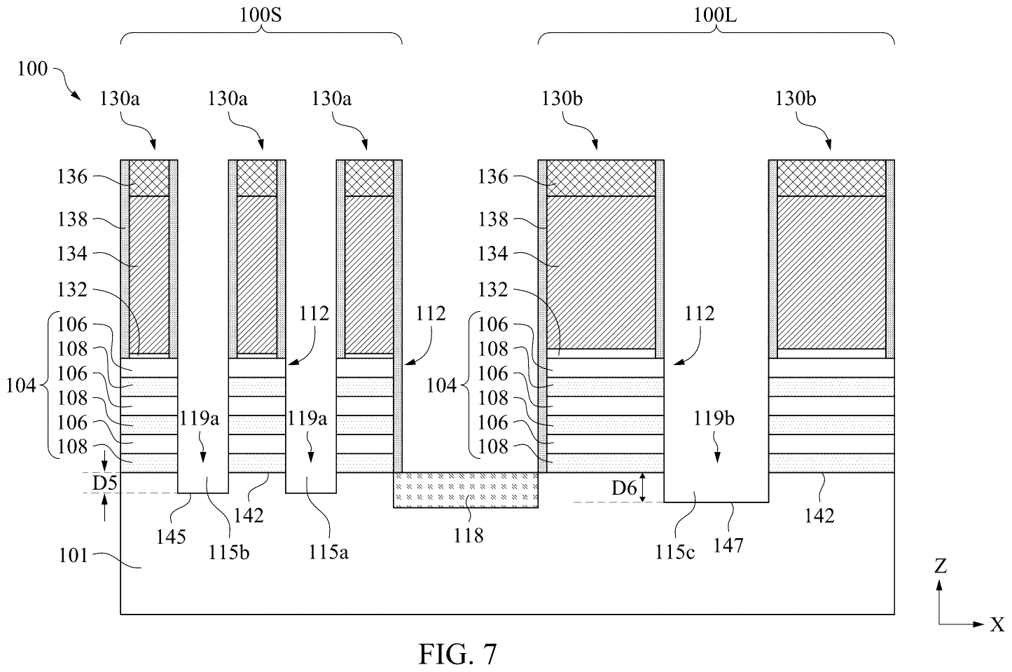

The fins 112 that are partially exposed on opposite sides of each sacrificial gate structures 130a, 130b define source/drain (S/D) regions for the semiconductor device structure 100. In some cases, some S/D regions may be shared between various transistors. For example, various ones of the S/D regions in the short channel region 100S may be connected together and implemented as multiple functional transistors. Likewise, various one of the S/D regions in the long channel region 100L may be connected together and implemented as multiple functional transistors. For exemplary illustration purposes, the region 115a (FIG. 7) between the sacrificial gate structures 130a in the short channel region 100S is designated as a source region/terminal, while the region 115b (FIG. 7) between the sacrificial gate structures 130a in the short channel region 100S is designated as a drain region/terminal. The region 115c (FIG. 7) between the sacrificial gate structures 130b in the long channel region 100L is designated as a drain region/terminal. However, it should be understood that the source region and the drain region can be interchangeably used since the epitaxial features to be formed in these regions are substantially the same.

Each sacrificial gate structure 130a in the short channel regions 100S is formed to have a first gate length L1, which is defined by the length of the sacrificial gate electrode layer 134 along the X direction in the short channel regions 100S. Each sacrificial gate structure 130b in the long channel regions 100L is formed to have a second gate length L2, which is defined by the length of the sacrificial gate electrode layer 134 along the X direction in the long channel regions 100L. The second gate length L2 is greater than the first gate length L1. Depending on the application and the size of the sacrificial gate structures 130a, 130b, the second gate length L2 can be equal to or greater than about 40 nm, for example greater than about 80 nm, and the first gate length L1 can be equal to or less than about 20 nm, for example less than about 15 nm. In general, a lateral separation distance “D3” between adjacent sacrificial gate structures 130a in the short channel regions 100S is less than a lateral separation distance “D4” between adjacent sacrificial gate structures 130b in the long channel regions 100L.

It should be noted that each sacrificial gate structure 130a in the short channel regions 100S and each sacrificial gate structure 130b in the long channel regions 100L need not be formed to have the same gate length. In addition, while three sacrificial gate structures 130a and two sacrificial gate structures 130b are shown in the short channel regions 100S and the long channel regions 100L, respectively, the number of the sacrificial gate structure should not be limited. The short channel regions 100S and the long channel regions 100L may each include any desired number of the sacrificial gate structures in the X direction in some embodiments.

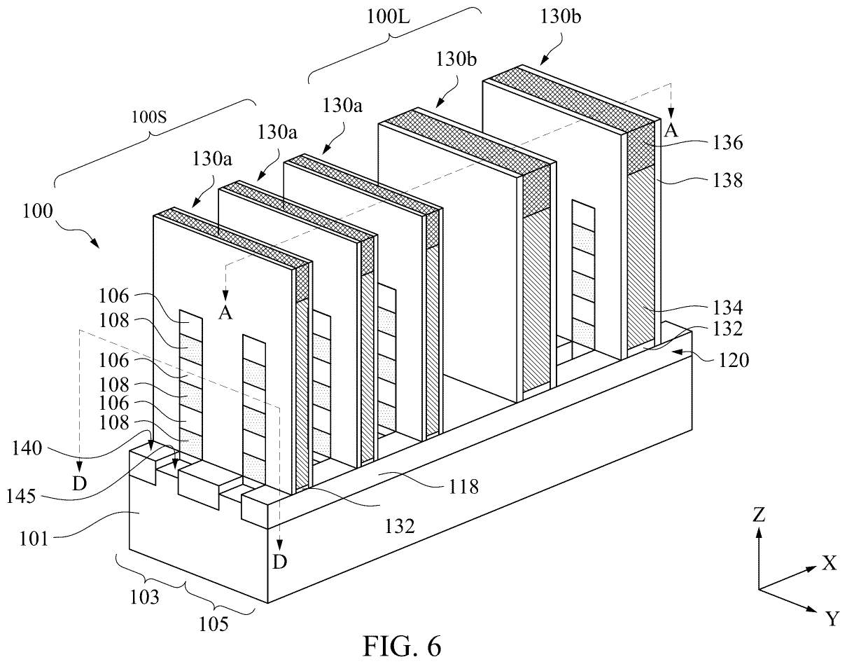

In FIG. 6, the portions of the fins 112 in the S/D regions (e.g., regions on opposite sides of the sacrificial gate structure 130) are recessed down below the top surface 140 of the isolation region 120 (or the insulating material 118), by removing portions of the fins 112 not covered by the sacrificial gate structures 130a, 130b. The recess of the portions of the fins 112 can be done by an etch process, cither isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119a, 119b (FIG. 7) are formed in the S/D regions as the result of the recess of the portions of the fins 112.

FIG. 7 is a cross-sectional side view of the semiconductor device structure 100 of FIG. 6 taken along line A-A. In some embodiments, the trenches 119a at the source/drain regions of the short channel region 100S may have a depth “D5”, which is a distance measuring from an interface surface 142 defined by the bottommost second semiconductor layer 108 and the substrate 101 under the sacrificial gate structure 130a to the bottom 145 of the trenches 119a. The trenches 119b at the source/drain regions of the long channel region 100L have a depth “D6”, which is a distance measuring from the interface surface 142 to the bottom 147 of the trenches 119b. The depth “D6” is greater than the depth “D5” due to loading effects of different etch processes between the short channel region 100S and the long channel region 100L. In one embodiment, the depth “D5” may be in a range between 5 nm and 30 nm, and the depth “D6” may be in a range between 10 nm and 40 nm.

In some embodiments, the etch process is performed such that the bottom 145 of the trenches 119a and the bottom 147 of the trenches 119b are at the same elevation as the interface surface 142.

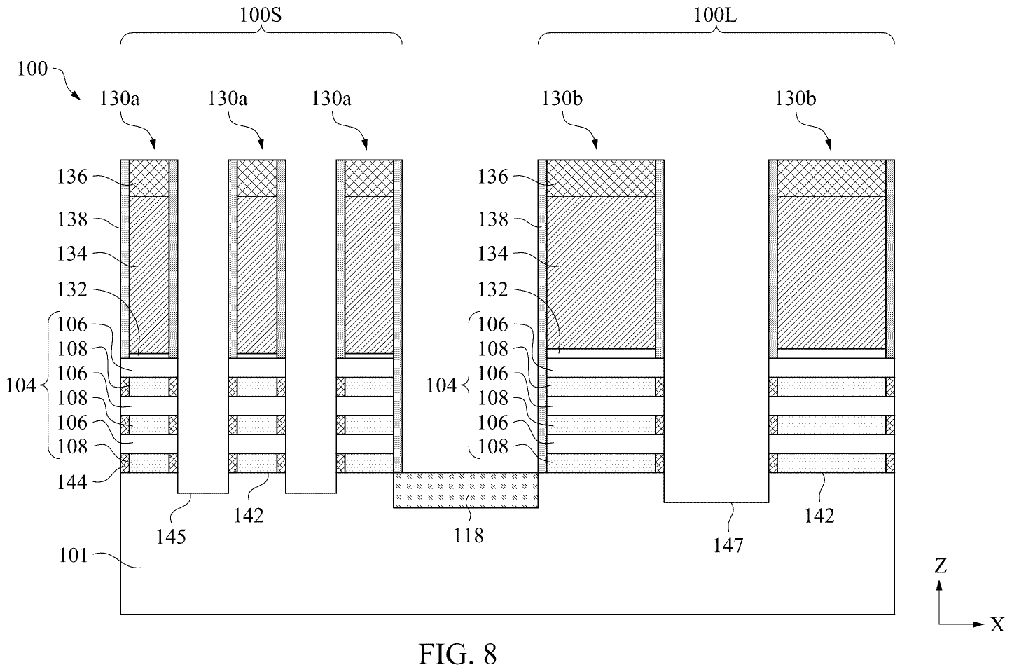

In FIG. 8, edge portions of each second semiconductor layer 108 of the stack of semiconductor layers 104 in the short channel region 100S and long channel region 100L are removed horizontally along the X direction. The removal of the edge portions of the second semiconductor layers 108 forms cavities. The portions of the second semiconductor layers 108 may be removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers (or so-called inner spacer) 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

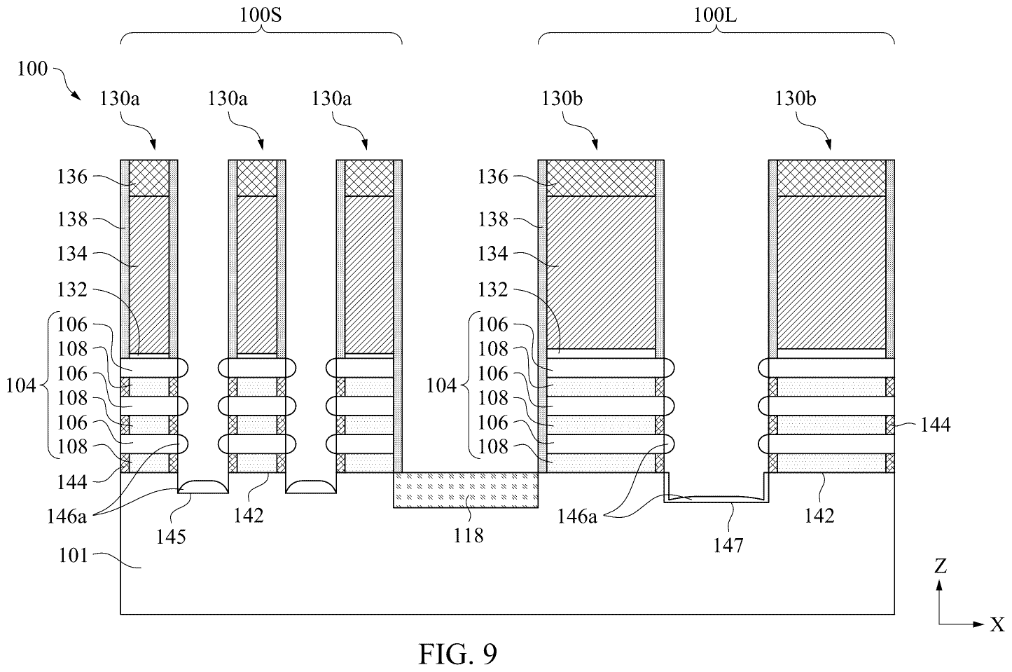

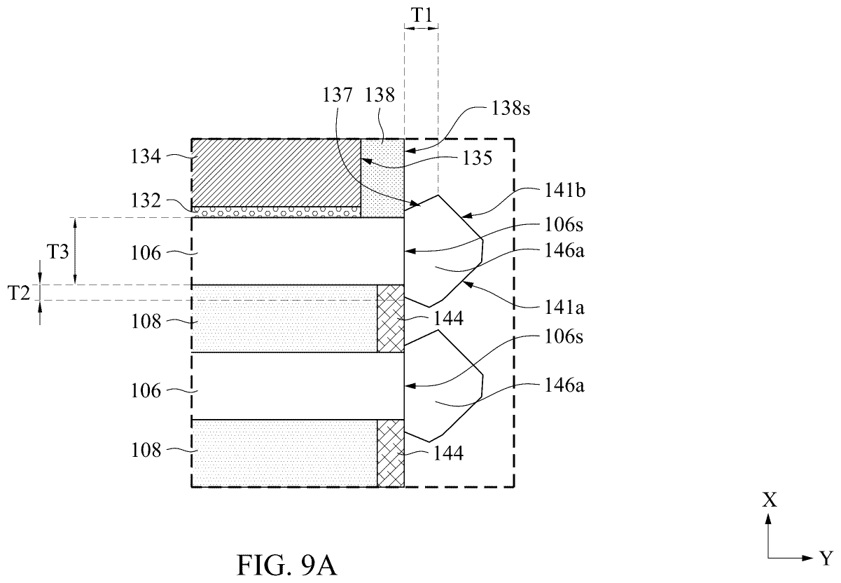

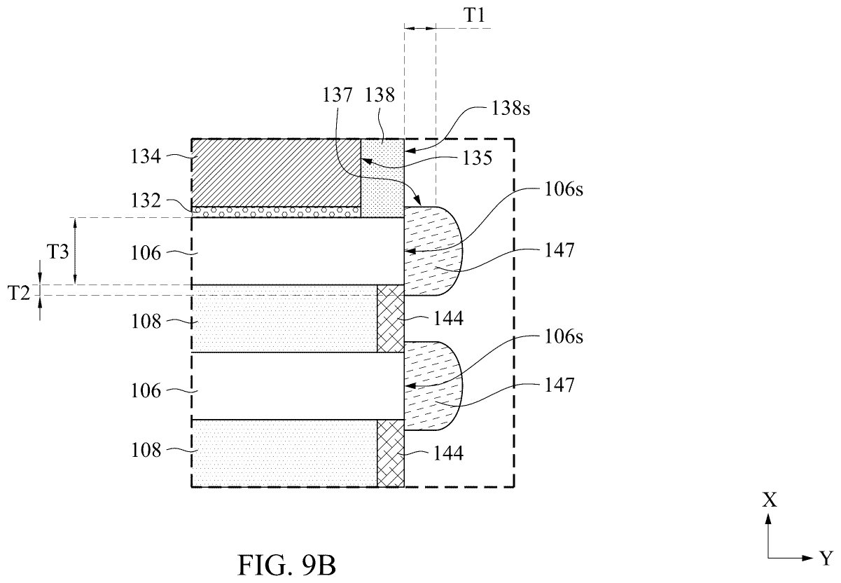

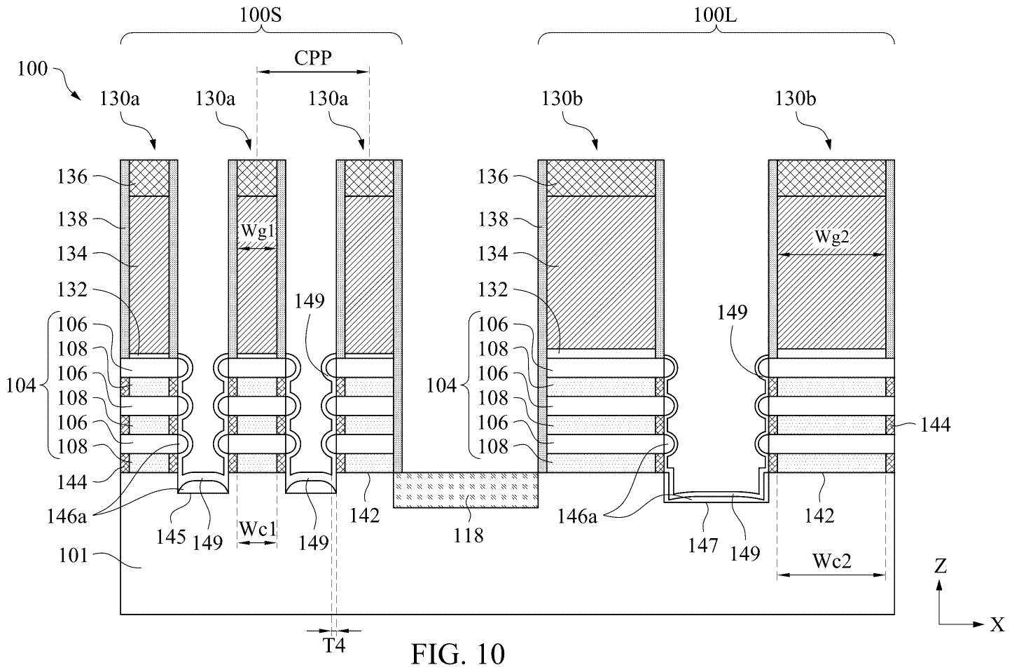

In FIG. 9, a first epitaxial layer 146a is formed on exposed surfaces of the first semiconductor layers 106 and the substrate 101. The epitaxial layer 146a promotes epitaxial growth of subsequent S/D features 146 may be considered as a part of subsequent S/D feature 146 (FIG. 10). In some embodiments, the first epitaxial layer 146a is formed of a doped semiconductor or doped semiconductor compound, such as Si, SiP, SiC, SiAs, and SiCP for n-channel FETs, or Si, SiGe, Ge for p-channel FETs, and may be formed using selective epitaxial growth (SEG), ALD, MBE, or any suitable growth process. The dopant may be chosen from a group III element, such as boron. For example, the first epitaxial layer 146a may be a boron-doped silicon (Si:B), a compound of boron and silicon, such as silicon triboride (SiB₃), silicon hexaboride (SiB₆), or the like, a boron-doped germanium (Ge:B), or a boron-doped silicon germanium (SiGe:B). In some embodiments, the first epitaxial layer 146a is a Ge-containing layer (e.g., SiGe) having a concentration of germanium in a range of about 0 at. % to about 20 at %. Depending on the application, the first epitaxial layer 146a may have a first dopant concentration that is equal to, lower, or higher than a dopant concentration of the subsequent second epitaxial layer 146b. The lower dopant concentration of the first epitaxial layer 146a avoids dopant diffusion into the channel regions (e.g., the region of the substrate 101 located below the sacrificial gate structures 130a, 130b and between adjacent epitaxial S/D features 146). In some embodiments, the first epitaxial layer 146a may be an undoped silicon layer.

The first epitaxial layer 146a may grow both vertically and horizontally to form facets, which may correspond to crystal planes of the material of the first semiconductor layers 106 and the substrate 101. Due to different growth rates on different surface planes, facets can be formed. For example, during the growth of the first epitaxial layer 146a, the growth rate on (111) planes of the first semiconductor layer 106 (e.g., silicon) may be lower than the growth rate on other planes, such as (110) and (100) planes of the first semiconductor layer 106. Therefore, facets are formed as a result of difference in growth rates of the different planes. The facet of the first epitaxial layer 146a may include a plane from the family of {111} planes, the family of {100} planes, and the family of {110} planes.

In one embodiment, the first epitaxial layer 146a is a facetted structure having a rhombus-like shape. In some embodiments, the first epitaxial layer 146a may have rounded-like surface. FIG. 9A illustrates an enlarged view of a portion of the semiconductor device structure 100 of FIG. 9 in accordance with some embodiments. As can be seen in FIG. 9A, the first epitaxial layer 146a is in contact with the sidewall 106s of the first semiconductor layer 106, the sacrificial gate dielectric layer 132, and the gate spacer 138. Particularly, the first epitaxial layer 146a extends across and covers the interface 135 defined by the gate spacer 138 and the sacrificial gate dielectric layer 132 (or the sacrificial gate electrode layer 134). The facetted structure is formed with at least facets 141a, 141b. The facets 141a-b of the facetted structure provide increased surface area to promote epitaxial growth of the S/D features. Particularly, the first epitaxial layer 146a extends over and covers the interface 135 defined by the gate spacer 138 and the sacrificial gate dielectric layer 132 (or the sacrificial gate electrode layer 134). In some embodiments, the first epitaxial layer 146a at and/or near an interface 137 defined by the first epitaxial layer 146a and the gate spacer 138 may extend along the Y-direction and have a thickness T1. The first epitaxial layer 146a may also extend along the X-direction to cover a portion of the dielectric spacer 144, and the first epitaxial layer 146a covering the dielectric spacer 144 may have a thickness T2. The topmost first semiconductor layer 106 may have a thickness T3. In some embodiments, the thickness T1 may be in a range of about 1 nm to about 10 nm. In some embodiments where the thickness T3 varies in a range of about 5 nm to about 60 nm, the thickness T1 or T2 may have a range of about 1 nm or less.

The embodiment shown in FIG. 9B is similar to that of FIG. 9A except the first epitaxial layer 147 on the first semiconductor layers 106 may not have facetted surface but a curved or rounded profile. The epitaxial layer 147 is in contact with the first semiconductor layer 106, the sacrificial gate dielectric layer 132, and the gate spacer 138. The epitaxial layer 147 may extend to cover the interface 135.

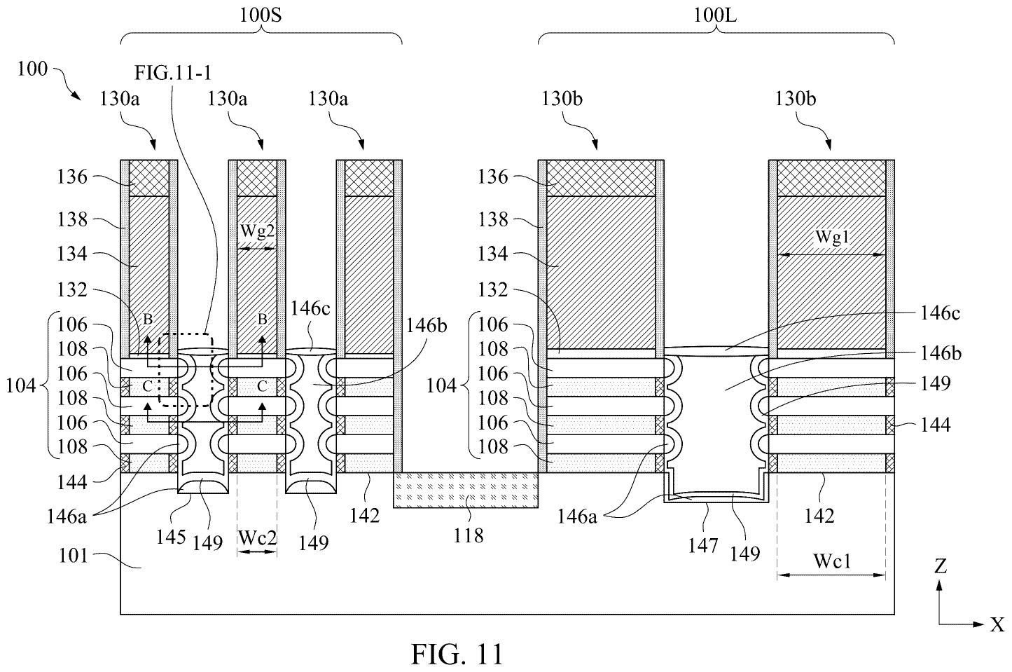

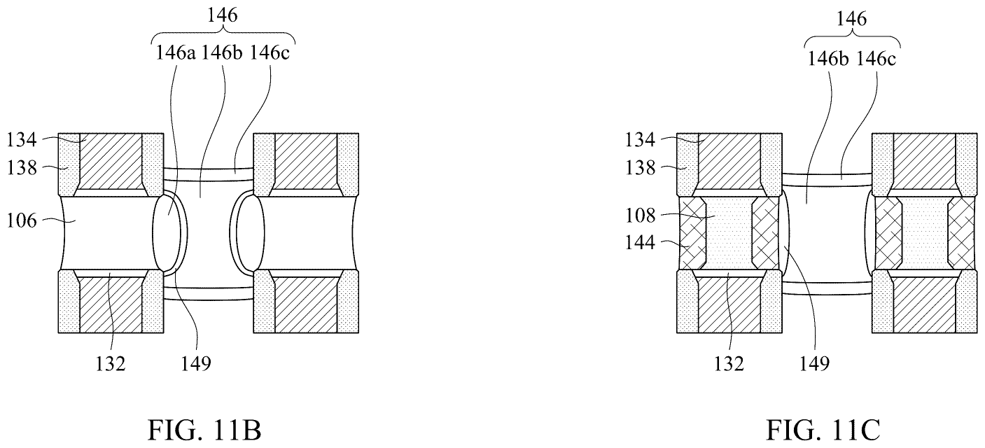

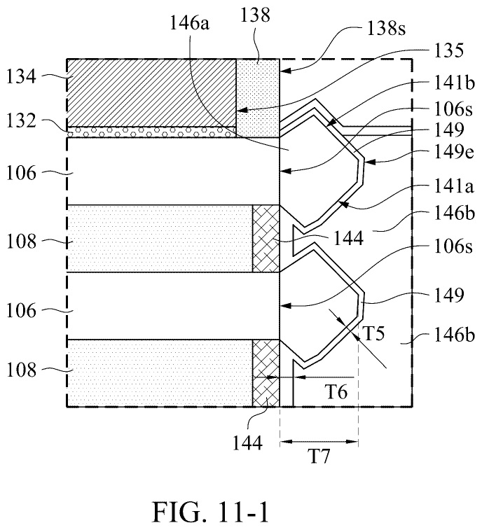

In FIG. 10, a dislocation stopping layer (DSL) 149 is formed on the exposed surfaces of the first epitaxial layer 146a for PMOS devices (e.g., P-type gate all around transistors) at the second device region 105. The DSL 149 is a continuous layer and the growth of the DSL 149 generally follows the profile of the first epitaxial layer 146a. In some embodiments, the DSL 149 has a curved profile in accordance with the exterior of the first epitaxial layer 146a. The DSL 149 prevents damage and/or lattice defects such as dislocations or stacking faults to the PMOS devices that may be generated as a result of lattice mismatch between the dielectric spacers 144 and the subsequent second epitaxial layer 146b (high Ge at. %). The presence of the DSL 149 thus blocks those plane defects from spreading over to the subsequent second epitaxial layer 146b. In addition, for PMOS devices, the epitaxial source/drain features (e.g., strain SiGe alloy) tends to relax lattice constant, and the relaxation process may induce stacking faults that can be observed at {111} orientation. The DSL 149 may function as a strain energy retention layer, which helps channel mobility for PMOS devices. The DSL 149 may also serve as a protection layer to prevent etchant chemicals (used during subsequent removal of the second semiconductor layers 108) from leaking through weak points such as the interface 135, the sidewall 138s of the gate spacer 138, and/or interface 137 (FIGS. 9A and 9B) and into the S/D features 146. If these weak points are not protected, the etch process to remove the second semiconductor layers 108 may also remove subsequently formed S/D features 146 (FIG. 11), resulting in damaged S/D features 146. In some cases, the S/D features 146 may be removed partially or even entirely by the etch process. The use of the DSL 149 ensures these weak points are blocked, which in turn minimizes the damage to the S/D features 146 during removal of the second semiconductor layers 108 (e.g., replacement gate process). As a result, the integrality of the S/D features 146 is preserved.

To form the DSL 149 for the PMOS devices at the second device region 105, a hard mask layer (not shown) may be first deposited on exposed surfaces of the semiconductor device 100, and a photoresist layer (not shown) is formed on the hard mask layer. The hard mask layer may be a conformal layer disposed on the exposed surfaces of the sacrificial gate structure 130, the first semiconductor layers 106, the dielectric spacer 144, and the first epitaxial layer 146a. The photoresist layer may be deposited on the hard mask layer until the sacrificial gate structures 130 are embedded within the photoresist layer. The hard mask layer is to be patterned to subsequently processing areas for one type of devices, such as N-type devices in the first device region 103 or P-type devices in the second device region 105.

A photolithography process is then performed to pattern the photoresist layer to expose processing areas for one type of devices, such as P-type device areas. The first device area 103 remains protected by the hard mask layer and the photoresist layer. In one exemplary embodiment, the photoresist layer at the second device region 105 is patterned to expose areas over the substrate 101 where P-type devices are to be formed. The photoresist layer may be removed by any suitable process, such as a wet strip process. After the photolithography process, an etch process is performed to remove the portion of the hard mask layer at the second device region 105. The etch process to remove the portion of the hard mask layer may include a wet etch process, exposing the processing areas for one type of devices, such as P-type device areas. The DSL 149 is then formed on the exposed surfaces of the first epitaxial layer 146a and the dielectric spacers 144.

The DSL 149 may be formed of a doped semiconductor or doped semiconductor compound, such as a doped silicon, a doped germanium, a doped silicon germanium, or the like. The DSL 149 and the first epitaxial layer 146a may include a material chemically different from each other. Due to the semiconductor material (of the DSL 149) being less attractive to the dielectric surface of the dielectric spacer 144 during the deposition, the DSL 149 may have higher deposition rate at the first epitaxial layer 146a than that at the dielectric spacer 144. As a result, the DSL 149 on the first epitaxial layer 146a may have a thickness T5 thicker than the thickness T6 of the DSL 149 on the dielectric spacers 144. In some embodiments, the difference between the thickness T5 and the thickness T6 is smaller than about 3 nm. The DSL 149 may have little or no deposition on the mask layer 136 and the gate spacers 138.

In some embodiments, the DSL 149 is a silicon-rich layer having a concentration of silicon of about 70 at. % or greater, for example in a range of about 80 at. % to about 95 at. %, with the rest being dopants chosen from a group III element, such as boron, a group IV element, such as carbon, germanium, or the like, or a combination thereof. The DSL 149 is etch-resist after incorporation of carbon dopants. In some embodiments, the DSL 149 and the first epitaxial layer 146a include SiGe and the DSL 149 has a germanium concentration of about the same or smaller than the germanium concentration of the first epitaxial layer 146a. In some embodiments, the DSL 149 is a Si or SiGe comprising boron and carbon. In some embodiments, the DSL 149 is a Si comprising boron, carbon, and germanium. In cases where the DSL 149 is a boron-doped semiconductor material or a chemical compound involving boron and a semiconductor material, the DSL 149 may be a boron-doped silicon (Si:B), a compound of boron and silicon, such as silicon triboride (SiB₃), silicon hexaboride (SiB₆), or the like, a boron-doped germanium (Ge:B), or a boron-doped silicon germanium (SiGe:B). In one embodiment, the DSL 149 is a boron-rich layer having a concentration of boron in a range of about 1 at. % to about 20 at. %. If the boron concentration is lower than about 1 at. %, the DSL 149 may not block the etchant leakage through the weak points during the subsequent replacement gate process. On the other hand, if the boron concentration is greater than about 20 at. %, the quality of the epitaxial film may be degraded and the manufacturing cost is increased without obvious additional advantages for blocking etchant leakage.

In some embodiments, the DSL 149, the first epitaxial layer 146a, and the second epitaxial layer 146b may each contain silicon, germanium, and boron (e.g., SiGe:B), in which (1) the DSL 149 may have a first concentration of silicon, the first epitaxial layer 146a may have a second concentration of silicon that is similar to or lower than the first concentration, and the second epitaxial layer 146b may have a third concentration of silicon that is lower than the first and second concentration; (2) the DSL 149 may have a first concentration of germanium, the first epitaxial layer 146a may have a second concentration of germanium that is similar to the first concentration, and the second epitaxial layer 146b may have a third concentration of germanium that is greater than the first and second concentration; and (3) the DSL 149 may have a first concentration of boron, the first epitaxial layer 146a may have a second concentration of boron that is similar to the first concentration, and the second epitaxial layer 146b may have a third concentration of boron that is greater than the second concentration. In some embodiments, the DSL 149 and the second epitaxial layer 146b may have a ratio of atomic percentage of silicon in a range of about 1.5:1 to about 6:1 (DSL 149:second epitaxial layer 146b). It is contemplated that the relationship of the concentration discussed herein is equally appliable to other DSL having different semiconductor material and dopants.

In some embodiments, the DSL 149 may have a dopant concentration in a range from about 0 to 2.5E22 atoms/cm³. In some examples, the DSL 149 may include silicon or silicon germanium having a boron concentration of about 0 to 5E21 atoms/cm³. In some examples, the DSL 149 may include silicon or silicon germanium having a carbon concentration of about 0 to 1E21 atoms/cm³. The dopants of boron, carbon, or germanium, for example, may be incorporated into the DSL 149 during the growth of the DSL 149 by an EPI process or after the formation of the DSL 149 by an implantation process. In some embodiments, the DSL 149 may be a strained or relaxed structure. The DSL 149 may have a thickness T4 in a range of about 3 Å to about 100 Å. It has been observed that the DSL 149 formed of silicon-rich or a highly doped semiconductor (e.g., Si:B, Si:C, or Si:Ge) can effectively block the leakage through the weak points. If the thickness of the DSL 149 is less than about 3 Å, the DSL 149 may not be thick enough to function as the leakage barrier layer nor the lattice transitional layer between the first epitaxial layer 146a and the subsequent second epitaxial layer 146b. The DSL 149 can also retard etchant chemicals used to remove the second semiconductor layers 108 during the formation of nanostructure channels in a multi-gate device. As a result, the integrality of the subsequent S/D feature 146 is protected. High boron-doped DSL 149 may also help reduce resistivity for the S/D features 146 (P-type EPI).

FIG. 10 also illustrates morphology of the DSL 149 on different length/width of the channel layers (i.e., first semiconductor layers 106) at the short channel region 100S and the long channel region 100L. As can be seen, each of the first semiconductor layers 106 at the short channel region 100S may have a channel width Wc1 and each of the first semiconductor layers 106 at the long channel region 100L may have a channel width Wc2 that is greater than the channel width Wc1. The channel widths Wc1 and Wc2 may be in a range of about 5 nm to about 40 nm. The gate length Wg1 of the sacrificial gate layer 134 at the short channel region 100S is less than the gate length Wg2 of the sacrificial gate layer 134 at the long channel region 100L. The gate height, which substantially equals to the thickness of the dielectric spacers 144, may be in a range of about 1 nm to about 15 nm. The contact poly pitch CPP may be in a range of about 20 nm to about 100 nm. The DSL 149 on the first epitaxial layer 146a above the substrate 101 may have a bottom thickness in a range of about 1 nm to about 10 nm, and the bottom thickness of the DSL 149 at the short channel region 100S may be greater than, or comparable to the bottom thickness of the DSL 149 at the long channel region 100L

Depending on the material of the DSL 149 to be formed, the exposed surfaces of the semiconductor device structure 100 may be exposed to a silicon-containing precursor(s), a germanium-containing precursor(s), a boron-containing precursor(s), an etching gas, and a diluent/carrier gas during the formation of the DSL 149. In cases where the DSL 149 includes boron-doped silicon germanium (SiGe:B), the DSL 149 may be formed by heating the semiconductor device structure 100 to a temperature of about 300 degrees Celsius to about 800 degrees Celsius, and exposing the first semiconductor layers 106 (and the substrate 101) to a precursor including at least a silicon-containing precursor, a germanium-containing precursor, and a boron-containing precursor. Suitable silicon-containing precursor may include, but is not limited to, silane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. Suitable germanium-containing precursor may include, but is not limited to, germane (GeH₄), digermane (Ge₂H₆), trigermane (Ge₃H₈), or germylsilane (GeH₆Si) or the like. Suitable gases for the boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. In cases etching gas(es) is used (e.g., in cyclic deposition etch (CDE) epitaxy process or selective etch growth (SEG) process), the deposition process may use one or more etching gases. Suitable etching gases may include, but are not limited to, hydrogen chloride (HCl), a chlorine gas (Cl₂), or the like. A diluent/purge gas, such as hydrogen (H₂), nitrogen (N₂), and/or argon (Ar), may be used along with the precursors for the DSL 149. In one embodiment, the DSL 149 is formed using precursors comprising SiH₄ and DCS, and B₂H₆. In another embodiment, the DSL 149 is formed using precursors comprising DCS, GeH₄, and B₂H6. In yet another embodiment, the DSL 149 is formed using precursors comprising DCS, GeH₄, and BCl₃. The formation of the DSL 149 may be performed in an epitaxial or CVD based reaction chamber.

In an exemplary embodiment, the DSL 149 is boron-doped silicon (Si:B) deposited by a CDE epitaxy process. The CDE epitaxy process may be performed in a process chamber at a temperature in a range between about 300° C. and 800° C., under a pressure in a range between about 1 Torr and 760 Torr, and performed for a time duration in a range between about 20 seconds and 300 seconds, by exposing the semiconductor device structure 100 to a gas mixture comprising one or more silicon-containing precursors (e.g., SiCl₂H₂, SiH₄, etc.), a p-type dopant gas (e.g., B₂H₆), and a carrier gas (e.g., Ar, H₂, etc.) for a first period of time to form a first portion of the DSL 149, followed by a selective etch where the first portion of the DSL 149 is exposed to etchants (e.g., HCl, etc.) for a second period of time to selectively remove amorphous or polycrystalline portions of the DSL 149 while leaving crystalline portions of the DSL 149 intact. The process chamber may be flowed with a purge gas (e.g., N₂) between the epitaxial growth and the selective etch. The silicon-containing precursor(s) may be provided at a flow rate in a range between about 10 sccm and about 500 sccm, the dopant gas may be provided at a flow rate in a range between about 10 sccm and about 300 sccm, the carrier gas may be provided at a flow rate in a range between about 0 sccm and about 50000 sccm, and the purge gas may be provided at a flow rate in a range between about 0 sccm and about 50000 sccm. The epitaxial growth and selective etch of the CDE epitaxy process are repeated until a desired thickness the DSL 149 and above-mentioned dopant concentration (e.g., first dopant concentration) are achieved.

Once the DSL 149 on the PMOS devices is formed, the hard mask layer and the photoresist layer at both first and second device regions 103, 105 are removed.

In FIG. 11, after formation of the DSL 149, the flow of the boron-containing precursor(s) may be terminated and group IV or group V precursor(s) are introduced into the process chamber along with the silicon-containing precursor(S) to form the rest of the S/D features 146. The S/D features 146 are formed in the S/D regions on opposing sides of the sacrificial gate structures 130 at the first and second device regions 103, 105. Therefore, the DSL 149 is formed of a material that is chemically different from that of the S/D features 146. The dopants in the S/D features 146 may be added during the formation of the S/D features 146, or after the formation of the S/D features 146 by an implantation process. The S/D epitaxial features 146 may include a second epitaxial layer 146b and a third epitaxial layer 146c formed on the first epitaxial layer 146a. The second epitaxial layer 146b forms a major portion of the epitaxial S/D feature 146. The second epitaxial layer 146b has at least three surfaces surrounded by or in contact with the DSL 149. The second and third epitaxial layers 146b, 146c may be formed by any suitable process, such as cyclic deposition etch (CDE) epitaxy process, selective etch growth (SEG) process, ALD, molecular beam epitaxy (MBE), or any combination thereof. The S/D features 146 may be the S/D regions. For example, one of a pair of S/D features 146 located on one side of the sacrificial gate structures 130 may be a source region, and the other of the pair of S/D features 146 located on the other side of the sacrificial gate structures 130 may be a drain region. A pair of S/D features 146 includes a source feature 146 and a drain feature 146 connected by the nanostructure channels (i.e., the first semiconductor layers 106). A source and a drain are interchangeably used in this disclosure.

The second epitaxial layer 146b is grown on the DSL 149 at the second device region 105 and on the first epitaxial layer 146a at the first device region 103, respectively. In some embodiments, the second epitaxial layer 146b is a semiconductor material, such as Si, SiP, SiC, SiAs, and SiCP for n-channel FETs, or Si, SiGe, Ge for p-channel FETs. Depending on the conductivity type of the device to be formed thereon, the second epitaxial layer 146b may have n-type dopants or p-type dopants. In either case, the second epitaxial layer 146b has a second dopant concentration that is comparable, greater, or lower than a dopant concentration of the third epitaxial layer 146c. In some embodiments, the second dopant concentration is in a range between about 1E19 atoms/cm³ and about 5E21 atoms/cm³.

The third epitaxial layer 146c is formed on the second epitaxial layer 146b. In some embodiments, a portion of the third epitaxial layer 146c is also in contact with the DSL 149. Similarly, the third epitaxial layer 146c may be a semiconductor material, such as Si, SiP, SiC, SiAs, and SiCP for n-channel FETs, or Si, SiGe, Ge for p-channel FETs. Depending on the conductivity type of the device to be formed, the third epitaxial layer 146c may have n-type dopants or p-type dopants. In either case, the third epitaxial layer 146c has a third dopant concentration higher than the second dopant concentration of the second epitaxial layer 146b. In some embodiments, the third dopant concentration is in a range between about 1E20 atoms/cm³ and about 5E21 atoms/cm³.

FIGS. 11B and 11C are top views of a portion of the semiconductor device structure 100 taken along cross-sections B-B and C-C of FIG. 11, respectively, in accordance with some embodiments. As can be seen in FIGS. 11B and 11C, the first epitaxial layer 146a is grown from the first semiconductor layer 106 and fully covered by the DSL 149. In some embodiments, the first epitaxial layer 146a is in contact with the gate spacers 138. The DSL 149 is disposed between and in contact with the dielectric spacers 144 and the second epitaxial layer 146b. In some embodiments, the DSL 149 may be in further contact with the gate spacers 138 and the third epitaxial layer 146c. FIG. 11-1 is an enlarged view of a portion of the semiconductor device structure 100 of FIG. 11 showing the DSL 149 on the first epitaxial layer 146a has a thickness T5 thinner than the thickness T6 of the DSL 149 on the dielectric spacers 144, due to the semiconductor material (of the DSL 149) being less attractive to the dielectric surface of the dielectric spacer 144 during the deposition. In some embodiments, the difference between the thickness T5 and the thickness T6 is smaller than about 3 nm. In one embodiment, the thickness T5 may be in a range of about 1 nm to about 10 nm. The thickness T6 may be in a range of about 0.5 nm to about 5 nm. In some embodiments, the thickness T5 and the thickness T6 may have a ratio of about 1:1.5 to about 1:4 (T5:T6). In some embodiments, the thickness T5 and the thickness T7 may have a ratio of about 1:3 to about 1:6 (T5:T7). In some embodiments, the thickness T6 and the thickness T7 may have a ratio of about 1:1.5 to about 1:2.5 (T6:T7). In some embodiments, the DSL 149 as deposited follows the surface profile of the first epitaxial layer 146a. For example, the DSL 149 on the facets 141a, 141b may each have a surface that is substantially parallel to the surface profile of the facets 141a, 141b, respectively.

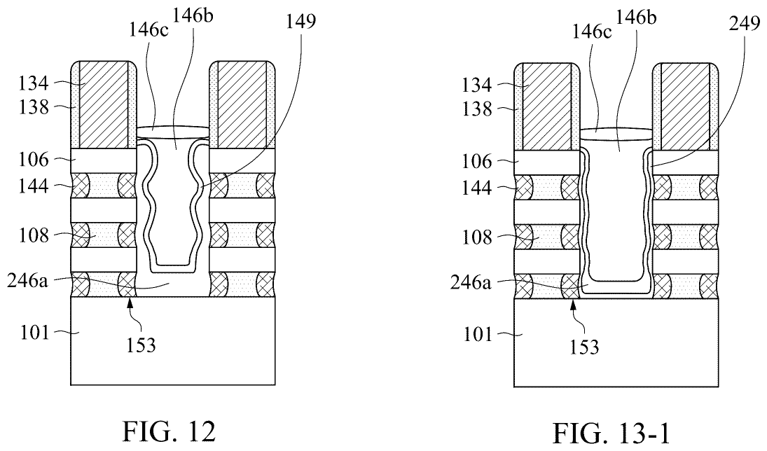

FIG. 12 is a cross-sectional view of the semiconductor device structure 100, in accordance with some alternative embodiments. The embodiment shown in FIG. 12 is similar to the embodiment shown in FIG. 11 except that a first epitaxial layer 246a (e.g., first epitaxial layer 146a) is grown from the first semiconductor layers 106 and extended to cover exposed surfaces of the first semiconductor layers 106, the dielectric spacers 144, and the substrate 101, and that the exposed top surface of the substrate 101 is at the same elevation as an interface 153 defined by the dielectric spacers 144 and the substrate 101. The exterior of the first epitaxial layer 146a may be formed to have a wavy profile. Thereafter, the DSL 149 is deposited, and the second epitaxial layer 146b and the third epitaxial layer 146c are sequentially deposited, in a similar fashion as discussed above with respect to FIGS. 10-12. It is contemplated that the elevation of the top surface of the substrate 101 is applicable to other embodiments of this disclosure.

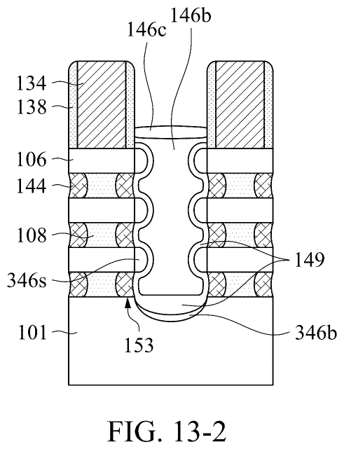

FIGS. 13-1 and 13-2 are cross-sectional views of the semiconductor device structure 100, in accordance with some alternative embodiments. The embodiment in FIG. 13-1 is similar to the embodiment shown in FIG. 11 except that a DSL 249 (e.g., DSL 149) is conformally formed as an initial layer on the exposed surfaces of the first semiconductor layers 106, the dielectric spacers 144, and the substrate 101. The first epitaxial layer 246a (e.g., first epitaxial layer 146a), the second epitaxial layer 146b, and the third epitaxial layer 146c are sequentially deposited on the DSL 249. The embodiment in FIG. 13-2 is similar to the embodiment shown in FIG. 11 except that a bottom first source/drain feature 346b has a curved profile corresponding to the bottom surface (e.g., bottom surface 145, 147) of the trenches 119a, 119b (FIG. 7). The DSL 149 is conformally formed on the exposed surfaces of the first source/drain features 346a on the sidewall of the first semiconductor layers 106, the dielectric spacers 144, and the bottom first source/drain feature 346b. The DSL 149 immediately above the bottom first source/drain feature 346a may have a surface at the same elevation as the interface 153 defined by the dielectric spacers 144 and the substrate 101.

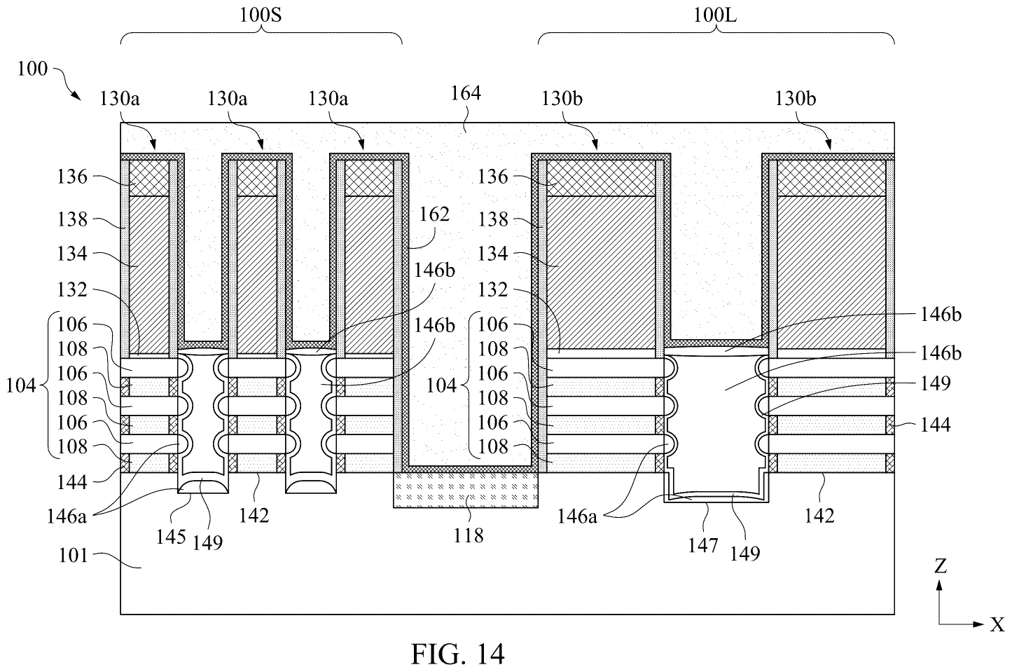

In FIG. 14, a contact etch stop layer (CESL) 162 is conformally formed on the exposed surfaces of the semiconductor device structure 100. The CESL 162 covers the sidewalls of the sacrificial gate structure 130a, 130b in the short and long channel regions 100S, 100L, the insulating material 118, and the epitaxial S/D features 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device structure 100. The first ILD layer 164 fills the trenches between the sacrificial gate structures 130a in the short channel region 100S, the trenches between the sacrificial gate structures 130b in the long channel region 100L, and the trench formed between the sacrificial gate structure 130a and the sacrificial gate structure 130b. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

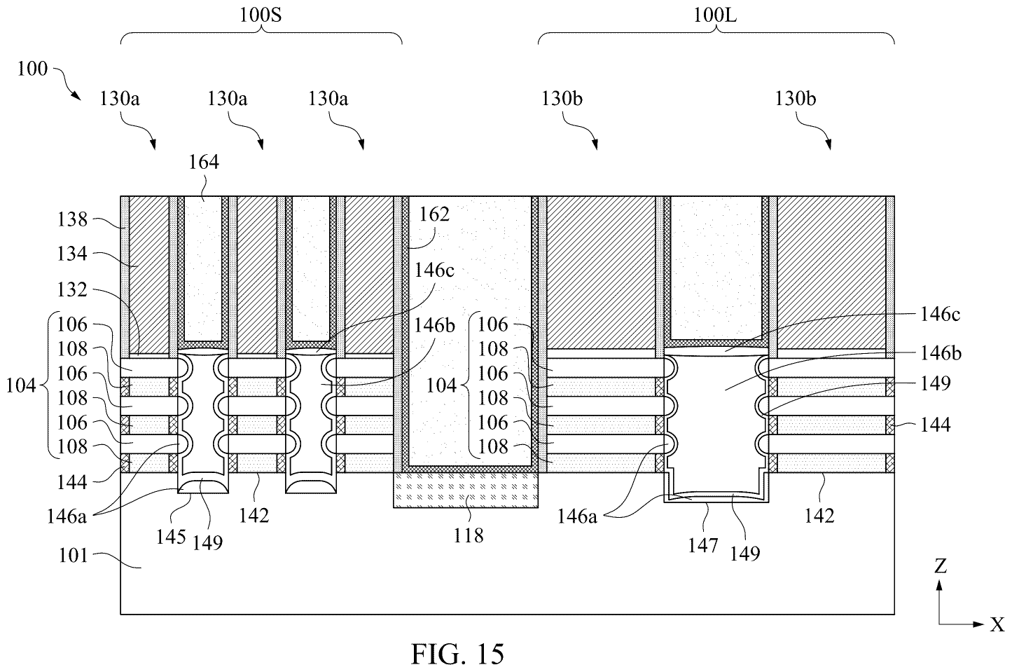

In FIG. 15, after the first ILD layer 164 is formed, a planarization operation, such as CMP, is performed on the semiconductor device structure 100 until the sacrificial gate electrode layer 134 is exposed.

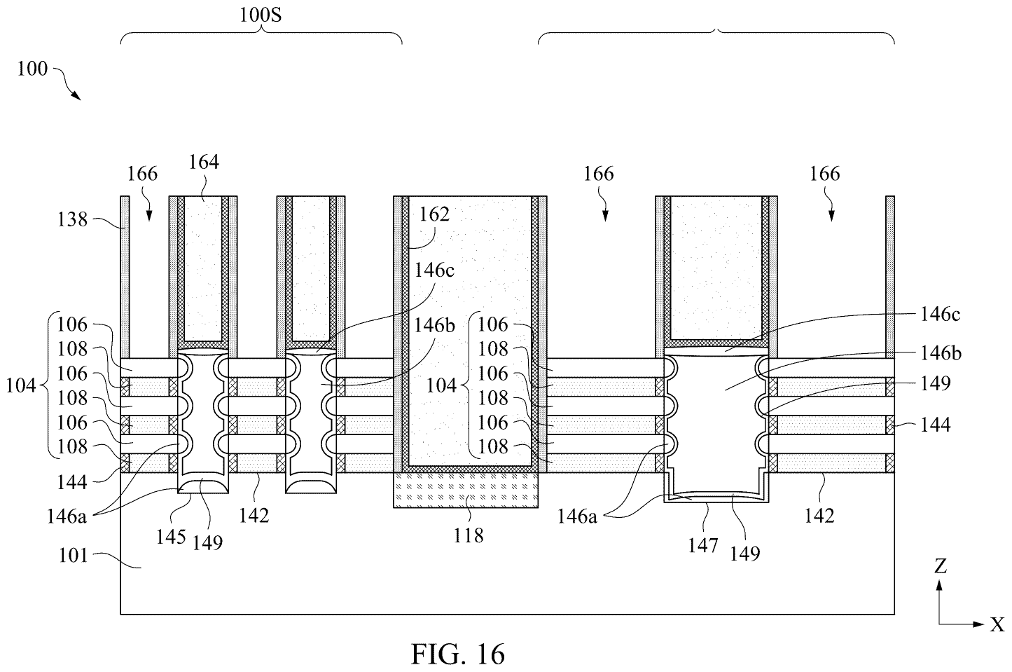

In FIG. 16, the sacrificial gate structures 130a, 130b in the short channel region 100S and the long channel region 100L are removed. The first ILD layer 164 protects the epitaxial S/D features 146 during the removal of the sacrificial gate structures 130a, 130b. The sacrificial gate structures 130a, 130b can be removed using plasma dry etching and/or wet etching. For example, in cases where the sacrificial gate electrode layer 134 is polysilicon and the first ILD layer 164 is silicon oxide, a wet etchant such as a tetramethylammonium hydroxide (TMAH) solution can be used to selectively remove the sacrificial gate electrode layer 134 without removing the dielectric materials of the first ILD layer 164, the CESL 162, and the gate spacers 138. The sacrificial gate dielectric layer 132 is thereafter removed using plasma dry etching and/or wet etching. The removal of the sacrificial gate structures 130a, 130b (i.e., the sacrificial gate electrode layer 134 and the sacrificial gate dielectric layer 132) forms a trench 166 in the regions where the sacrificial gate electrode layer 134 and the sacrificial gate dielectric layer 132 were removed. The trench 166 exposes the top and sides of the stack of semiconductor layers 104 (e.g., the first semiconductor layers 106 and the second semiconductor layers 108).

In FIG. 17, the second semiconductor layers 108 are removed, leaving the first semiconductor layers 106 and the dielectric spacers 144. After the sacrificial gate dielectric layer 132 and the sacrificial gate electrode layer 134 are removed, the first semiconductor layers 106 and the second semiconductor layers 108 in the short channel region 100S and the long channel region 100L are exposed. The removal of the second semiconductor layers 108 result in gaps formed between the dielectric spacers 144, and the first semiconductor layers 106 connecting the epitaxial S/D features 146. Each first semiconductor layer 106 may have a surface along the longitudinal direction of the semiconductor layer 106, and the majority of that surface is exposed as the result of the removal of the second semiconductor layers 108. The exposed surface will be surrounded by a gate electrode layer formed subsequently. Each first semiconductor layer 106 forms a nanosheet channel of the nanosheet transistor.

The second semiconductor layers 108 may be removed using any suitable selective removal process, such as selective wet etching process. In cases where the second semiconductor layers 108 are made of SiGe or Ge and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, ammonium hydroxide (NH₄OH), tetramethylammonium hydroxide (TMAH), ethylenediamine pyrocatechol (EDP), or potassium hydroxide (KOH) solution.

After the formation of the nanosheet channels (i.e., the exposed first semiconductor layers 106), a gate dielectric layer 170 is formed around each first semiconductor layer 106, and a gate electrode layer 172 is formed on the gate dielectric layer 170, surrounding a portion of each first semiconductor layer 106, as shown in FIG. 17. The gate dielectric layer 170 and the gate electrode layer 172 in the long channel region 100L may be collectively referred to as a gate structure 174a, and the gate dielectric layer 170 and the gate electrode layer 172 in the short channel region 100S may be collectively referred to as a gate structure 174b. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO2, HfSiO, HfSiON, HfTaO, HfTiO, HfZrO, zirconium oxide, aluminum oxide, titanium oxide, hafnium dioxide-alumina (HfO2-Al2O3) alloy, other suitable high-K dielectric materials, and/or combinations thereof. The gate dielectric layer 170 may be formed by CVD, ALD or any suitable deposition technique. In one embodiment, the gate dielectric layer 170 is formed using a conformal deposition process such as ALD in order to ensure the formation of a gate dielectric layer having a uniform thickness around each first semiconductor layer 106.

The gate electrode layer 172 is formed on the gate dielectric layer 170 to surround a portion of each first semiconductor layer 106. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the first ILD layer 164. The gate dielectric layer 170 and the gate electrode layer 172 formed over the first ILD layer 164 are then removed by using, for example, CMP, until the top surface of the first ILD layer 164 is exposed.

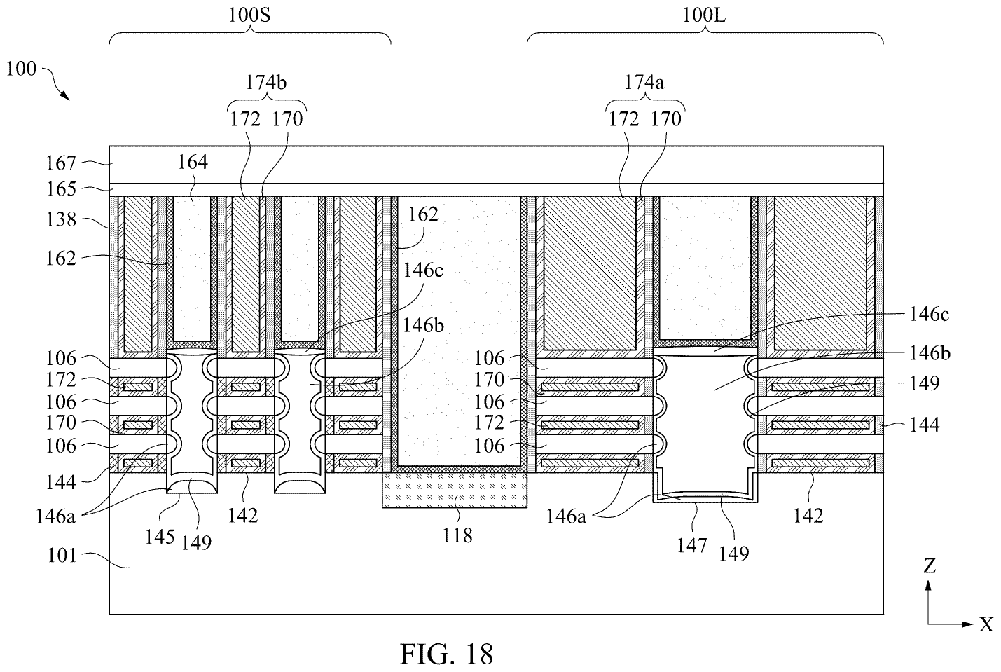

In FIG. 18, an etch stop layer 165 is formed on the semiconductor device structure 100 and over the gate structures 174a, 174b (e.g., the planarized gate spacer 138, gate dielectric layer 170, and gate electrode layer 172) and the remaining CESL 162 and first ILD layer 164. Thereafter, a second ILD layer 167, such as the first ILD layer 164, is formed on the etch stop layer 165. The etch stop layer 165 may be formed of a dielectric material that can be used to protect the underlying layers during subsequent trench and via patterning for metal contacts. In some embodiments, the etch stop layer 165 includes the same material as the CESL 162. The etch stop layer 165 and the second ILD layer 167 may be formed of a dielectric material that is chemically different from each other.

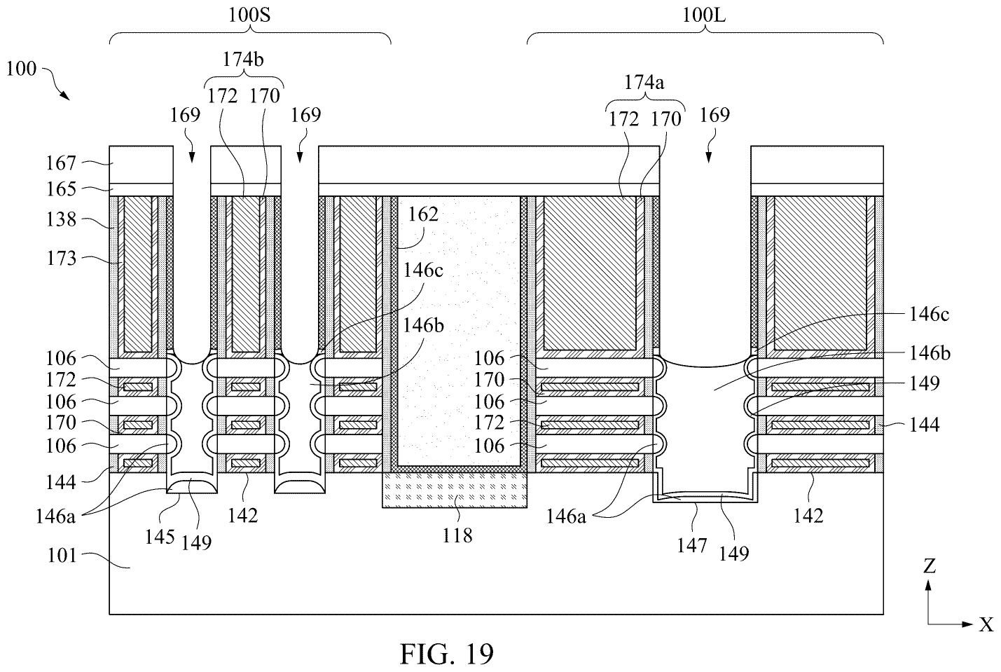

In FIG. 19, contact openings 169 are formed through the second ILD layer 167, the etch stop layer 165, the first ILD layer 164, the CESL 162, and the third epitaxial layer 146c in the short channel region 100S and the long channel region 100L to expose a portion of the epitaxial S/D features 146 (e.g., the second epitaxial layer 146b). The etched surface of the epitaxial S/D features 146 may have a planar profile, or a non-planar profile, such as a concave profile (dishing), or a convex profile (protruded). The contact openings 169 are to be filled with a conductive material to form the source/drain metal contacts. The contact openings 169 may be formed by any suitable photolithographic and etching techniques.

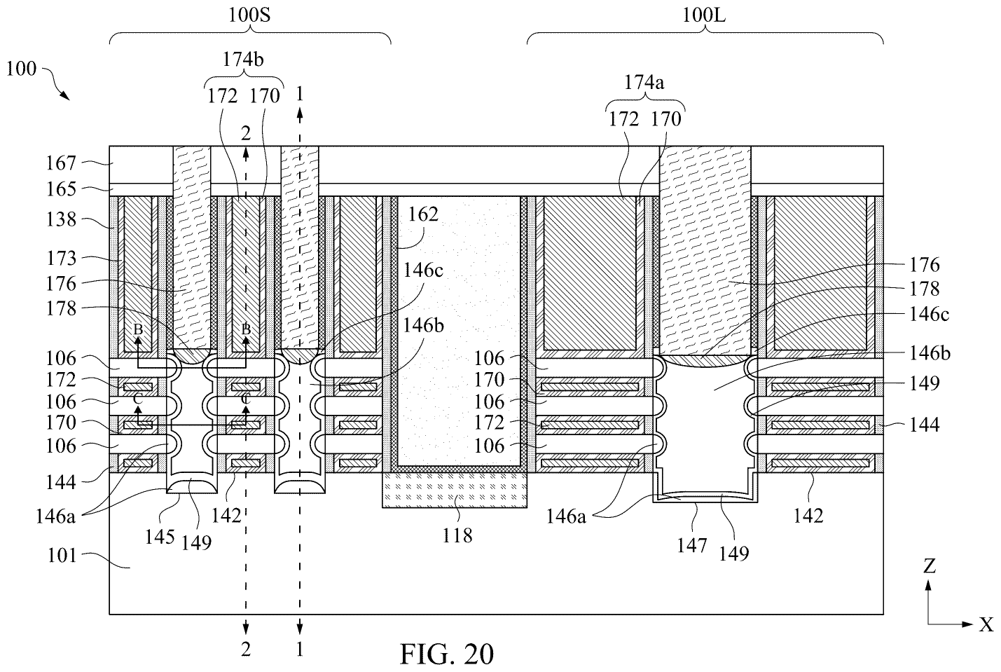

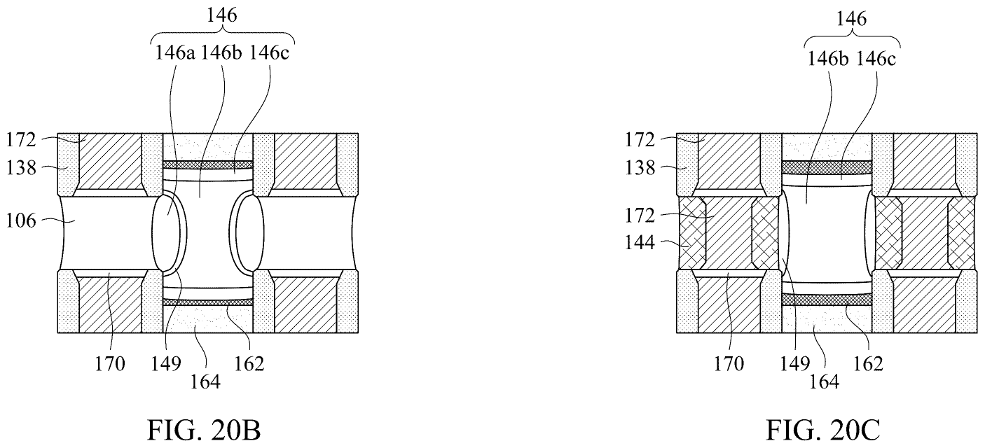

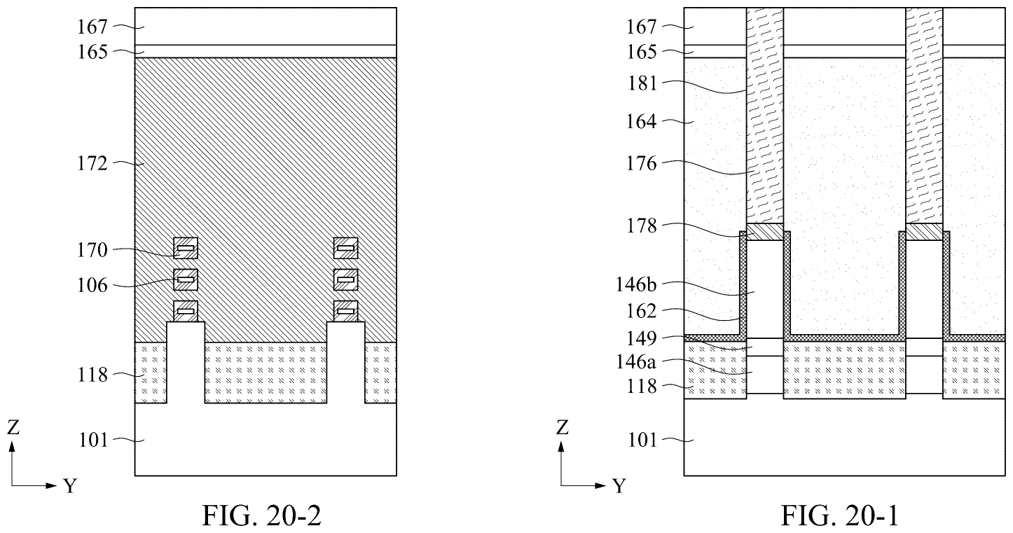

In FIG. 20, the front side S/D contacts 176 are formed in contact openings 169. After the formation of the contact openings, a silicide layer 178 is formed on the epitaxial S/D features 146 at the short channel region 100S and the long channel region 100L, respectively. The bottom of the silicide layer 178 may have a profile (e.g., a concave profile) in accordance with the profile of the upper portion of the epitaxial S/D features 146. The silicide layer 178 conductively couples the epitaxial S/D features 146 to the subsequently formed front side S/D contacts 176. The silicide layer 178 may be formed by depositing a metal source layer over the epitaxial S/D features 146 and performing a rapid thermal annealing process. During the rapid anneal process, the portion of the metal source layer over the epitaxial S/D features 146 reacts with silicon in the epitaxial S/D features 146 to form the silicide layer 178. Unreacted portion of the metal source layer is then removed. For n-channel FETs, the silicide layer 178 may be made of a material including one or more of TiSi, CrSi, TaSi, MoSi, ZrSi, HfSi, ScSi, Ysi, HoSi, TbSI, GdSi, LuSi, DySi, ErSi, YbSi, or combinations thereof. For p-channel FETs, the silicide layer 178 may be made of a material including one or more of NiSi, CoSi, MnSi, Wsi, FeSi, RhSi, PdSi, RuSi, PtSi, IrSi, OsSi, or combinations thereof. In some embodiments, the silicide layer 178 is made of a metal or metal alloy silicide, and the metal includes a noble metal, a refractory metal, a rare earth metal, alloys thereof, or combinations thereof. Next, a conductive material is formed in the contact openings 169 and form the front side S/D contacts 176. The conductive material may be made of a material including one or more of Ru, Mo, Co, Ni. W, Ti, Ta, Cu, Al, TiN and TaN, and can be formed by CVD, ALD, electro-plating, or other suitable deposition technique. While not shown, a barrier layer (e.g., TiN, TaN, or the like) may be formed on sidewalls of the contact openings prior to forming the front side S/D contacts 176.

After the front side S/D contacts 176 are formed, an etch back process may be performed and an optional dielectric cap material (not shown) may be formed on the front side S/D contacts 176 in the short channel region 100S and the long channel region 100L, respectively. The dielectric cap material may be deposited using a deposition process, such as CVD, PECVD, or FCVD or any suitable deposition technique. A planarization process, such as CMP, is then performed to remove excess deposition of the dielectric cap layer and expose the top surface of the second ILD layer 167. The dielectric cap material may include or be formed of oxygen-containing materials, nitrogen-containing materials, or silicon-containing materials. Exemplary materials for the dielectric cap layer may include, but are not limited to, SiC, SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or any combinations thereof. The dielectric cap material can have different etch selectivity than the second ILD layer 167 so as to selective etch back the dielectric cap layer.

The front side S/D contacts 176 formed over the epitaxial S/D features 146 (e.g., the epitaxial S/D feature 146 formed over the drain region 115b) may be connected to signal lines in the subsequent formed front side interconnect structure. In some embodiments, the front side S/D contacts are formed over the epitaxial S/D features 146 (e.g., the epitaxial S/D feature 146 formed over the source region 115a, FIG. 7) for structural balance in the device, and the epitaxial S/D feature 146 formed over the source region 115a is to be connected to a power rail, such as a positive voltage (VDD) or a negative voltage (VSS or GND) disposed on a backside of the substrate 101. In such a case, the epitaxial S/D feature 146 are not further connected to any contacts subsequently formed in a front side interconnect structure.

FIGS. 20B and 20C are top views of a portion of the semiconductor device structure 100 taken along cross-sections B-B and C-C of FIG. 20, respectively, in accordance with some embodiments. FIGS. 20-1 and 20-2 are cross-sectional views of the semiconductor device structure 100 taken along line 1-1 and line 2-2 of FIG. 20, respectively.

The semiconductor device structure 100 may then undergo further complementary metal oxide semiconductor (CMOS) and/or back-end-of-line (BEOL) processes to form various features such as transistors, contacts/vias, interconnect metal layers, dielectric layers, passivation layers, etc.

Various embodiments or examples described herein offer multiple advantages over the state-of-art technology. According to embodiments of the present disclosure, stacking fault and wire release induced damages to S/D features of nanostructure channel FETs can be prevented by providing a dislocation stopping layer (DSL) 149 between a dielectric spacer (inner spacer) 144 and the epitaxial source/drain features 146 prior to gate replacement process. The DSL 149 is a silicon-rich semiconductor or compound material and can be doped (e.g., Si:B) to effectively block plane defects from spreading over and/or etchant chemicals used during nanostructure formation process from leaking to the S/D features. As a result, the integrality of the S/D features is preserved.

An embodiment is a semiconductor device structure. The structure includes a plurality of semiconductor layers vertically stacked, a gate electrode layer surrounding a portion of each of the plurality of the semiconductor layers, a gate dielectric layer disposed between the gate electrode layer and each of the semiconductor layer, a first source/drain feature in contact with a sidewall of each of the semiconductor layers, wherein the first source/drain feature comprises a first semiconductor material. The structure also includes a dielectric spacer in contact with the gate dielectric layer, and a protection layer in contact with the dielectric spacer and the first source/drain feature, wherein the protection layer comprises a second semiconductor material that is chemically different than the first semiconductor material.

Another embodiment is a semiconductor device structure. The structure includes a plurality of semiconductor layers vertically stacked, a gate spacer in contact with a topmost semiconductor layer of the plurality of semiconductor layers, a dielectric spacer disposed between and in contact with two adjacent semiconductor layers, a first source/drain feature in contact with a sidewall of the first semiconductor layer and a sidewall of the dielectric spacer, wherein the first source/drain feature comprises a first semiconductor material. The structure also includes a protection layer in contact with the gate spacer and exposed surface of the first source/drain feature, and a second source/drain feature in contact with the protection layer and the gate spacer, the second source/drain feature comprising a second semiconductor material chemically different than the first semiconductor material.

A further embodiment is a method for forming a semiconductor device structure. The method includes forming a plurality of semiconductor layers vertically and parallelly stacked over a substrate, forming a trench exposing a sidewall of each semiconductor layer, forming a dielectric spacer between two adjacent semiconductor layers, forming a first source/drain feature on the sidewall of each semiconductor layer, forming a protection layer on exposed surfaces of the first source/drain features and the dielectric spacers, and forming a second source/drain feature on the protection layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a plurality of semiconductor layers vertically stacked;
a gate electrode layer surrounding a portion of each of the plurality of the semiconductor layers;
a gate dielectric layer disposed between the gate electrode layer and each of the semiconductor layer;
a first source/drain feature in contact with a sidewall of each of the semiconductor layers, wherein the first source/drain feature comprises a first semiconductor material;
a dielectric spacer in contact with the gate dielectric layer; and
a protection layer in contact with the dielectric spacer and the first source/drain feature, wherein the protection layer comprises a second semiconductor material that is chemically different than the first semiconductor material.

2. The semiconductor device structure of claim 1, further comprising:
a second source/drain feature comprising a first surface, a second surface opposing the first surface, and a sidewall connecting the first surface to the second surface, wherein the second source/drain feature comprises a third semiconductor material that is chemically different than the first semiconductor material.

3. The semiconductor device structure of claim 2, wherein the second semiconductor material has a first germanium concentration and the third semiconductor material has a second germanium concentration that is greater than the first germanium concentration.

4. The semiconductor device structure of claim 2, wherein the protection layer comprises a first portion disposed between and in contact with the first source/drain feature and the second source/drain feature.

5. The semiconductor device structure of claim 4, wherein the protection layer comprises a second portion disposed between and in contact with the dielectric spacer and the second source/drain feature.

6. The semiconductor device structure of claim 5, wherein the first portion has a first thickness and the second portion has a second thickness greater than the first thickness.

7. The semiconductor device structure of claim 2, wherein the second semiconductor material has a first silicon concentration and the third semiconductor material has a second silicon concentration, and the first silicon concentration and the second silicon concentration have a ratio of about 1.5:1 to about 6:1.

8. The semiconductor device structure of claim 7, wherein the second semiconductor material comprises a first dopant from a group III element.

9. The semiconductor device structure of claim 8, wherein the second semiconductor material comprises a second dopant from a group IV element.

10. The semiconductor device structure of claim 3, further comprising:
a third source/drain feature disposed above the second source/drain feature, the third source/drain feature being in contact with the protection layer.

11. The semiconductor device structure of claim 10, further comprising:
a gate spacer in contact with the gate dielectric layer, the semiconductor layer, and the third source/drain feature.

12. The semiconductor device structure of claim 2, further comprising:
a silicide layer in contact with the first surface of the second source/drain feature and the protection layer.

13. A semiconductor device structure, comprising:
a plurality of semiconductor layers vertically stacked;
a gate spacer in contact with a topmost semiconductor layer of the plurality of semiconductor layers;
a dielectric spacer disposed between and in contact with two adjacent semiconductor layers;
a first source/drain feature in contact with a sidewall of the first semiconductor layer and a sidewall of the dielectric spacer, the first source/drain feature comprising a first semiconductor material;
a protection layer in contact with the gate spacer and exposed surface of the first source/drain feature; and
a second source/drain feature in contact with the protection layer and the gate spacer, the second source/drain feature comprising a second semiconductor material chemically different than the first semiconductor material.

14. The semiconductor device structure of claim 13, further comprising:
a third source/drain feature in contact with the gate spacer and the second source/drain feature, the third source/drain feature comprising a third semiconductor material chemically different than the second semiconductor material.

15. The semiconductor device structure of claim 13, further comprising:
a third source/drain feature in contact with the gate spacer and the protection layer, the third source/drain feature comprising a third semiconductor material chemically different than the second semiconductor material.

16. The semiconductor device structure of claim 15, further comprising:
an interlayer dielectric (ILD) layer; and
a contact etch stop layer (CESL) disposed between and in contact with the ILD layer and the third source/drain feature.

17. The semiconductor device structure of claim 15, wherein the first epitaxial source/drain feature has a first germanium concentration, the protection layer has a second germanium concentration equal to or less than the first epitaxial source/drain feature, the second epitaxial source/drain feature has a third germanium concentration greater than the second germanium concentration.

18. The semiconductor device structure of claim 13, wherein a bottom of the protection layer has a curved profile.

19. A method for forming a semiconductor device structure, comprising:
forming a plurality of semiconductor layers vertically and parallelly stacked over a substrate;
forming a trench exposing a sidewall of each semiconductor layer;
forming a dielectric spacer between two adjacent semiconductor layers;
forming a first source/drain feature on the sidewall of each semiconductor layer;
forming a protection layer on exposed surfaces of the first source/drain features and the dielectric spacers; and
forming a second source/drain feature on the protection layer.

20. The method of claim 19, wherein the first source/drain feature, the second source/drain feature, and the protection layer have a germanium concentration different from each other.
